(19) United States
(12) Patent Application Publication
(10) Pub. No.: US 2017/0069377 A1
(43) Pub. Date: Mar. 9, 2017

(54) MEMORY DEVICE

(71) Applicant: Kabushiki Kaisha Toshiba, Minato-ku (JP)

(72) Inventors: Masatoshi KOHNO, Kawaguchi (JP); Masami MASUDA, Chigasaki (JP); Hayato KONNO, Yokohama (JP); Akihiro IMAMOTO, Yokohama (JP)

(73) Assignee: Kabushiki Kaisha Toshiba, Minato-ku (JP)

(21) Appl. No.: 15/057,252

(22) Filed: Mar. 1, 2016

Related U.S. Application Data
(60) Provisional application No. 62/215,957, filed on Sep. 9, 2015.

(51) Int. Cl. G11C 13/00

(52) U.S. Cl. CPC G11C 13/0061; G11C 13/0038; G11C 13/0097

(57) ABSTRACT

According to one embodiment, a memory device includes a memory cell array configured to store data and a clock generator configured to generate a clock signal, the memory device outputs data held in the memory cell array in accordance with a timing of the clock signal, and the clock generator generates the clock signal with a substantially constant gradient each time a power supply is turned on.

### CROSS REFERENCE TO RELATED APPLICATIONS

This application claims the benefit of U.S. Provisional Application No. 62/215,957, filed Sep. 9, 2015, the entire contents of which are incorporated herein by reference.

### FIELD

The present embodiment relates to a memory device.

### BACKGROUND

The operating speed of memory devices has been increasingly higher.

### BRIEF DESCRIPTION OF THE DRAWINGS

FIG. 1 is a block diagram schematically depicting a basic configuration of a NAND flash memory according to a first embodiment;

FIG. 2 is a circuit diagram depicting a basic configuration of a clock generator included in the NAND flash memory according to the first embodiment;

FIG. 3 is a circuit diagram depicting a basic configuration of a trimming circuit included in the NAND flash memory according to the first embodiment;

FIG. 4 is a waveform diagram illustrating a read operation in the NAND flash memory according to the first embodiment;

FIG. 5 is a waveform diagram of a data strobe signal;

FIG. 6 is a block diagram illustrating the operation of generating the trimming control signal in the NAND flash memory according to the first embodiment;

FIG. 7 is a block diagram illustrating the operation of generating the trimming control signal in the NAND flash memory according to the first embodiment;

FIG. 8 is a block diagram illustrating the operation of generating the trimming control signal in the NAND flash memory according to the first embodiment;

FIG. 9 is a circuit diagram depicting a basic configuration of a trimming circuit included in a NAND flash memory according to a second embodiment; and

FIG. 10 is a block diagram illustrating an operation of generating a trimming control signal in the NAND flash memory according to the second embodiment.

### DETAILED DESCRIPTION

In general, according to one embodiment, a memory device includes a memory cell array configured to store data and a clock generator configured to generate a clock signal, the memory device outputs data held in the memory cell array in accordance with a timing of the clock signal, and the clock generator generates the clock signal with a substantially constant gradient each time a power supply is turned on.

Embodiments will be described below with reference to the drawings. In the description, common portions are denoted by common reference numerals throughout the drawings.

### <1> First Embodiment

A semiconductor memory device according to an embodiment will be described.

<1-1> Configuration

<1-1-1> Configuration of the Memory System

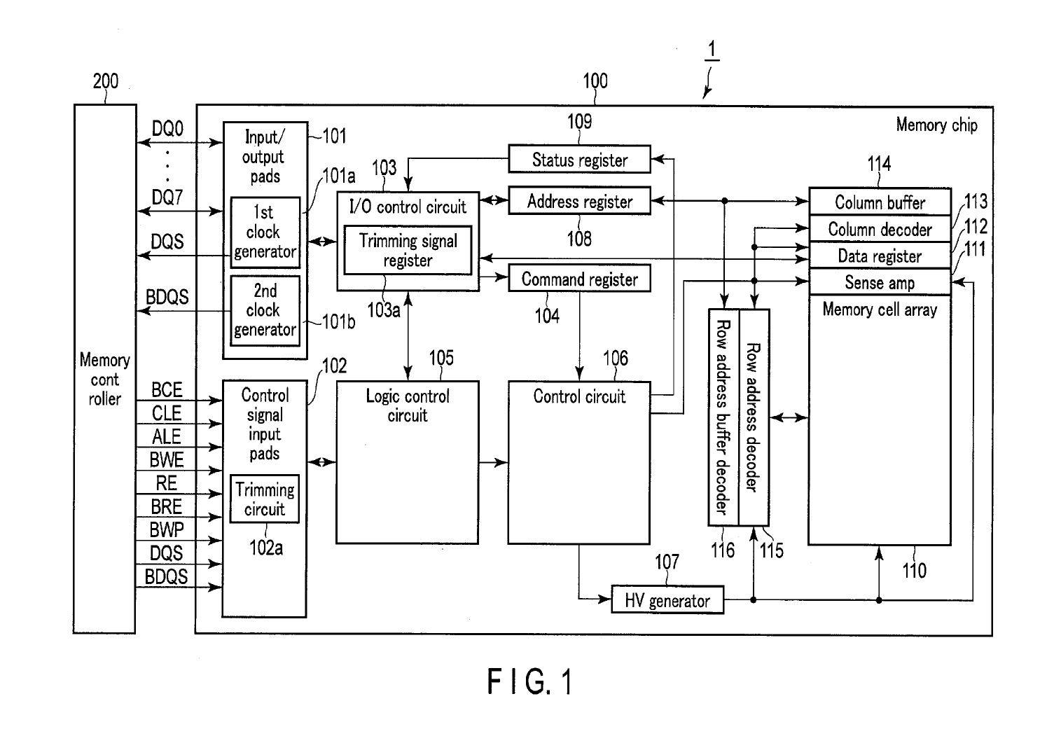

A configuration of a memory system including the semiconductor memory device according to the present embodiment will be described using FIG. 1.

As depicted in FIG. 1, a memory system 1 comprises a memory chip (semiconductor memory device) 100 and a memory controller 200. The memory chip 100 and the memory controller 200 may, for example, be combined together to form one semiconductor device. Examples of the semiconductor device include a memory card such as an SD™ card and an SSD (Solid State Drive). The memory system 1 may further comprise a host device (not depicted in the drawings).

<1-1-2> Memory Controller

The memory controller 200 outputs, for example, commands needed for operations of the memory chip 100, to the memory chip 100. By outputting the commands to the memory chip 100, the memory controller 200 reads data from the memory chip 100, writes data to the memory chip 100, or deletes data from the memory chip 100.

<1-1-3> Memory Chip

The memory chip 100 according to the present embodiment will be described using FIG. 1.

The memory controller 200 and the memory chip 100 are connected together via input/output pads 101 and control signal input pads 102.

The input/output pads 101 comprise a first clock generator 101a and a second clock generator 101b. The first clock generator 101a generates a data strobe signal DQS in accordance with a signal supplied by an input/output control circuit 103. The second clock generator 101b generates a data strobe signal BDQS (a complementary signal for DQS) in accordance with a signal supplied by the input/output control circuit 103. In outputting data through data input/output lines (DQ0 to DQ7), the input/output pads 101 output the data strobe signals DQS and BDQS. The memory controller 200 receives data through the data input/output lines (DQ0 to DQ7) in accordance with timings of the data strobe signals DQS and BDQS.

Furthermore, the input/output pads 101 comprise, for example, a command input terminal and an address input terminal.

The control signal input pads 102 comprise a trimming circuit 102a. The trimming circuit 102a is a circuit that generates a trimming control signal for trimming the first clock generator 101a and the second clock generator 101b. Details of the trimming circuit 102a will be described below. Upon receiving a trimming signal based on a trimming control signal via the input/output control circuit 103, the first clock generator 101a and the second clock generator 101b adjust the data strobe signals DQS and BDQS.

The control signal input pads 102 receive, from the memory controller 200, a chip enable signal BCE (Bar Chip Enable), a command latch enable signal CLE (Command Latch Enable), an address latch enable signal ALE (Address Latch Enable), a write enable signal BWE (Bar Write Enable), a read enable signal RE (Read Enable), a read enable signal BRE (Bar Read Enable), a write protect signal BWP (Bar Write Protect), a data strobe signal DQS, and the data strobe signal BDQS.

The chip enable signal BCE is used as a select signal for the memory chip 100.

The command latch enable signal CLE is a signal used to load an operation command into a command register 104.

The address latch enable signal ALE is a signal used to load address information or input data into an address register 108 or a data register 112.

The write enable signal BWE is a signal for loading a command, an address, and data on the input/output pads 101 into the memory chip 100.

The read enable signal RE is a signal used to allow data to be serially output through the input/output pads 101. The read enable signal BRE is a complementary signal of RE.

The write enable signal BWE is used to protect data from unexpected erasure or write when an input signal is undefined, for example, when the memory chip 100 is powered on or off.

Although not depicted in FIG. 1, an R/B terminal indicating an internal operation state of the memory chip 100, a Vcc/Vss/Vccq/Vssq terminal for power supply, and the like are also provided in the memory chip 100.

The input/output control circuit 103 outputs data read from a memory cell array 110 via the input/output pads 101, to the memory controller 200. The input/output control circuit 103 receives various commands such as a write command, a read command, an erase command, and a status read command, an address, and write data via the control signal input pads 102 and a logic control circuit 105.

The input/output control circuit 103 allows a logic control circuit 105 to generate a trimming control signal.

The input/output control circuit 103 comprises a trimming signal register 103a and stores the trimming control signal received from the logic control circuit 105 or an initial value. The trimming control signal may, for example, be stored in the memory cell array 110 and read into the trimming control signal register 103a when the memory chip 100 is started. Furthermore, the trimming control signal may be updated each time a new trimming control signal is supplied by the logic control circuit 105. Additionally, the trimming control signal generated by the logic control circuit 105 may be stored in the memory cell array 110 as needed.

The command register 104 outputs commands received from the input/output control circuit 103, to a control circuit 106.

The logic control circuit 105 supplies control signals received via the control signal input pads 102 to the input/output control circuit 103 and the control circuit 106. The logic control circuit 105 generates the trimming control signal using the trimming circuit 102a in accordance with instructions from the input/output control circuit 103.

The control circuit 106 controls an HV generator 107, a sense amplifier 111, a data register 112, a column decoder 113, a row address decoder 115, and a status register 109.

The control circuit 106 operates in accordance with control signals received via the logic control circuit 105 and commands received via the command register 104. At the time of programming, verification, read, and erasure, the control circuit 106 supplies desired voltages to the memory cell array 110, the sense amplifier 111, and the row address decoder 115 using the HV generator 107.

In the present embodiment, the input/output control circuit 103, the logic control circuit 105, and the control circuit 106 have been described according to functions. However, the input/output control circuit 103, the logic control circuit 105, and the control circuit 106 may be implemented using the same hardware resource.

The address register 108, for example, latches an address supplied by the memory controller 200. The address register 108 then converts the latched address into an internal physical address (a column address and a row address). The address register 108 supplies the column address to a column buffer 114, while supplying the row address to a row address buffer decoder 116.

The status register 109 is configured to inform an external device of various states inside the memory chip 100. The status register 109 has a ready/busy register that holds data indicating whether the memory chip 100 is either in a ready state or in a busy state and a write register (not depicted in the drawings) that holds data indicating whether write has passed or failed.

The memory cell array 110 comprises a plurality of bit lines BL, a plurality of word lines WL, and a source line SL. The memory cell array 110 includes a plurality of blocks BLK in each of which a plurality of electrically rewritable memory cell transistors (also simply referred to as memory cells) MC is arranged in a matrix. The memory cell transistor MC, for example, has a stack gate including a control gate electrode and a charge accumulation layer (for example, floating gate electrode). The memory cell transistor MC stores binary data or multivalued data based on a change in a threshold for the transistor set determined by the amount of charge injected into the floating gate electrode. Furthermore, the memory cell transistor MC may have a MONOS (Metal-Oxide-Nitride-Oxide-Silicon) structure in which electrons are trapped in a nitride film.

The configuration of the memory cell array 110 is disclosed in U.S. patent application Ser. No. 12/397,711 filed Mar. 3, 2009 and entitled “SEMICONDUCTOR MEMORY DEVICE HAVING PLURALITY OF TYPES OF MEMORIES INTEGRATED ON ONE CHIP”. In addition, the configuration thereof is disclosed in U.S. patent application Ser. No. 13/451,185 filed Apr. 19, 2012 and entitled “SEMICONDUCTOR MEMORY DEVICE INCLUDING STACKD GATE HAVING CHARGE ACCUMULATION LAYER AND CONTROL GATE AND METHOD OF WRITING DATA TO SEMICONDUCTOR MEMORY DEVICE”, in U.S. patent application Ser. No. 12/405,626 filed Mar. 17, 2009 and entitled “NONVOLATILE SEMICONDUCTOR MEMORY ELEMENT, NONVOLATILE SEMICONDUCTOR MEMORY, AND METHOD FOR OPERATING NONVOLATILE SEMICONDUCTOR MEMORY ELEMENT”, in U.S. patent application Ser. No. 09/956,986 filed Sep. 21, 2001 and entitled “NONVOLATILE SEMICONDUCTOR MEMORY DEVICE HAVING ELEMENT ISOLATING REGION OF TRENCH TYPE AND METHOD OF MANUFACTURING THE SAME”, in U.S. patent application Ser. No. 12/407,403 filed 19 Mar. 2009 and entitled “three dimensional stacked nonvolatile semiconductor memory”, in addition, the configuration thereof is disclosed in U.S. patent application Ser. No. 12/406,524 filed 18 Mar. 2009 and entitled “three dimensional stacked nonvolatile semiconductor memory”, in U.S. patent application Ser. No. 13/816,799 filed 22 Sep. 2011 and entitled “nonvolatile semiconductor memory device”, and in U.S. patent application Ser. No. 12/532,030 filed 23 Mar. 2009 and entitled “semiconductor memory and method for manufacturing the same”. The entire descriptions of these patent applications are incorporated by reference herein.

During a data read operation, the sense amplifier 111 senses data read from the memory cell transistor MC onto the bit line.

The data register 112 comprises a SRAM. The data register 112 stores, for example, data supplied by the memory controller 200 and verify results detected by the sense amplifier 111.

The column decoder 113 decodes a column address signal stored in the column buffer 114, and outputs, to the sense amplifier 111, a select signal that allows any one of the bit lines BL to be selected.

The column buffer 114 temporarily stores the column address signal received from the address register 108.

The row address decoder 115 decodes a row address signal received via a row address buffer decoder 116. The row address decoder 115 selects from the word lines WL and select gate lines SGD, SGS in the memory cell array 110 for driving.

The row address buffer decoder 116 temporarily stores a row address signal received from the address register 108.

<1-1-3-1> Basic Configuration of the Clock Generator

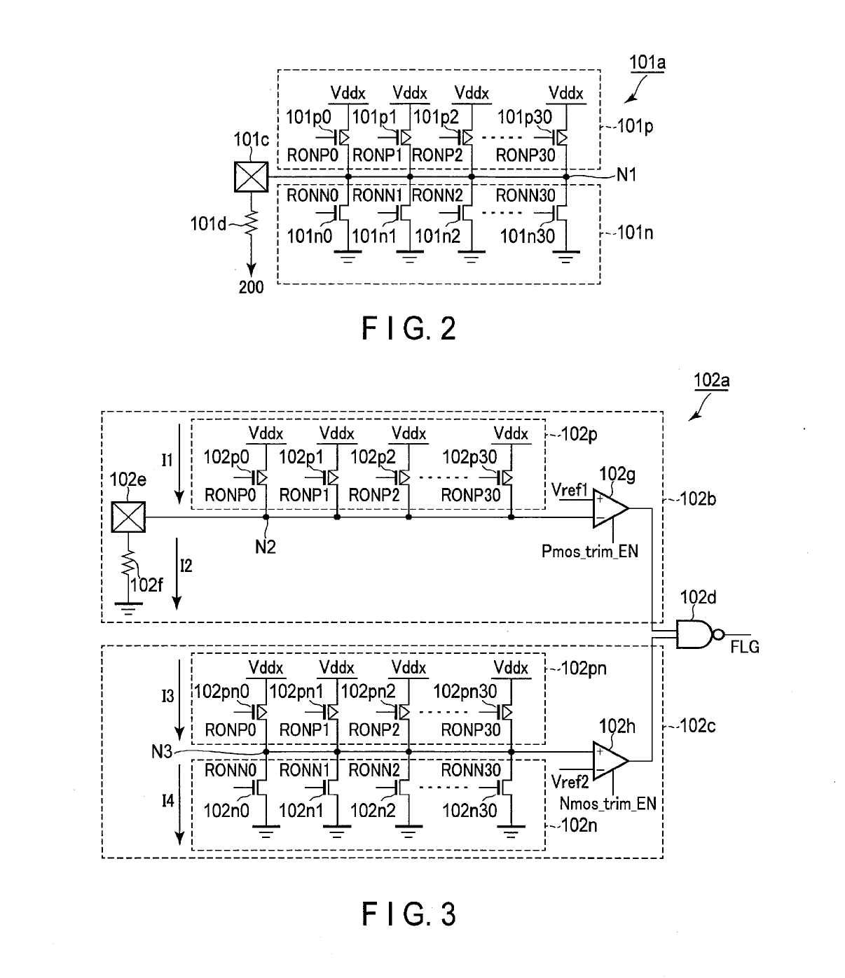

The first clock generator 101a will be described using FIG. 2. As depicted in FIG. 2, the first clock generator 101a generates the data strobe signal DQS using a PMOS (P-type Metal Oxide Semiconductor) transistor group 101p and an NMOS (N-type Metal Oxide Semiconductor) transistor group 101n. The first clock generator 101a outputs the data strobe signal DQS to the memory controller 200 via a pad 101c connected to a node N1 and a wire 101d. In FIG. 2, with a wiring resistance of the wire 101d taken into account, the wire 101d is depicted as a resistance element.

The PMOS transistor group 101p comprises, for example, 31 PMOS transistors (101p0 to 101p30). A trimming signal RONP0 is input to a gate of the PMOS transistor 101p0. A voltage Vddx is applied to an end (source) of the PMOS transistor 101p0. The other end (drain) of the PMOS transistor 101p0 is connected to a node N1. As depicted in FIG. 2, trimming signals RONP1 to RONP30 are input to gates of the PMOS transistors 101p1 to 101p30. The voltage Vddx is applied to ends (sources) of the PMOS transistors 101p1 to 101p30. The other ends of the PMOS transistors 101p1 to 101p30 are connected to the node N1. When not distinguished from one another, the trimming signals RONP0 to RONP30 are simply described as the trimming signal RONP.

The NMOS transistor group 101n comprises, for example, 31 NMOS transistors (101n0 to 101n30). A trimming signal RONN0 is input to a gate of the NMOS transistor 101n0. An end (drain) of the NMOS transistor 101n0 is connected to the node N1. The other end (source) of the NMOS transistor 101n0 is connected to a ground potential (GND). As depicted in FIG. 2, trimming signals RONN1 to RONN30 are input to gates of the NMOS transistors 101n1 to 101n30. Ends (drains) of the NMOS transistors 101n1 to 101n30 are connected to the node N1. The other ends of the NMOS transistors 101n1 to 101n30 are connected to the ground potential (GND). When not distinguished from one another, the trimming signals RONN0 to ROMN30 are simply described as the trimming signal RONN.

The input/output control circuit 103 generates the trimming signals RONP and RONN based on the trimming control signal stored in the trimming signal register 103a. Furthermore, the input/output control circuit 103, for example, supplies the trimming signals RONP0 to RONP30 and the trimming signals RONN0 to RONN30 to the first clock generator 101a based on the read enable signal RE (or BRE) received from the logic control circuit 105.

The first clock generator 101a charges the node N1 based on the trimming signals RONP0 to RONP30. When the node N1 is charged, the data strobe signal DQS rises. The first clock generator 101a discharges the node N1 based on the trimming signals RONN0 to RONN30. When the node N1 is discharged, the data strobe signal DQS falls.

The configuration of the second clock generator 101b is similar to the configuration of the first clock generator 101a and will not be described below. The input/output control circuit 103, for example, supplies the trimming signals RONP0 to RONP30 and RONN0 to RONN30 to the second clock generator 101b based on the read enable signal BRE (or RE) received from the logic control circuit 105.

The second clock generator 101b charges a node not depicted in the drawings based on the trimming signals RONP0 to RONP30. When the node not depicted in the drawings is charged, the data strobe signal BDQS rises. The second clock generator 101b discharges the node not depicted in the drawings based on the trimming signals RONN0 to RONN30. When the node not depicted in the drawings is discharged, the data strobe signal BDQS falls.

The case where the PMOS transistor group 101p comprises the 31 PMOS transistors has been described. However, the PMOS transistor group 101p may comprise 30 or less PMOS transistors or 32 or more PMOS transistors. In this case, the number of trimming signals RONP increases and decreases consistently with the number of PMOS transistors. This also applies to the NMOS transistor group 101n. Furthermore, the number of transistors included in the PMOS transistor group 101p may be the same as or different from the number of transistors included in the NMOS transistor group 101n.

<1-1-3-2> Basic Configuration of the Trimming Circuit

The trimming circuit 102a will be described using FIG. 3. The trimming circuit 102a comprises a PMOS trimming circuit 102b, an NMOS trimming circuit 102c, and a NAND circuit 102d. The logic control circuit 105 generates the trimming control signal using the trimming circuit 102a. The trimming control signal includes, for example, a DAC value RONPdac (not depicted in the drawings) related to the trimming signal RONP and a DAC value RONNdac (not depicted in the drawings) related to the trimming signal RONN. The DAC value RONPdac is a value obtained by adjusting those of the trimming signals RONP0 to RONP30 which are set to an “L (Low) level”. The DAC value RONNdac is a value obtained by adjusting those of the trimming signals RONN0 to RONN30 which are set to an “H (High) level”. A specific method for generating these values will be described below.

The PMOS trimming circuit 102b enables generation of a current similar to a current flowing through a PMOS transistor group 102p, the pad 101c, and the wire 101d in the first clock generator 101a or the second clock generator 101b.

The logic control circuit 105 generates the DAC value RONPdac related to the trimming signal RONP using the PMOS trimming circuit 102b. The PMOS trimming circuit 102b comprises the PMOS transistor group 102p, a pad 102e, a resistance element 102f, and a comparator 102g.

The PMOS transistor group 102p is configured similarly to the PMOS transistor group 101p in the first clock generator 101a or the second clock generator 101b. Specifically, the PMOS transistor group 102p comprises 31 PMOS transistors (102p0 to 102p30) similarly to the PMOS transistor group 101p. In other words, the number of transistors included in the PMOS transistor group 102p is equal to the number of transistors included in the PMOS transistor group 101p in the first clock generator 101a or the second clock generator 101b. The trimming signal RONP0 is input to a gate of the PMOS transistor 102p0. The voltage Vddx is applied an end (source) of the PMOS transistor 102p0. The other end of the PMOS transistor 102p0 is connected to a node N2. As depicted in FIG. 3, the trimming signals RONP1 to RONP30 are input to gates of the PMOS transistors 102p1 to 102p30. Furthermore, the voltage Vddx is applied ends (sources) of the PMOS transistors 102p1 to 102p30. The other ends of the PMOS transistors 102p1 to 102p30 are connected to the node N2. In FIG. 3, the sum of currents flowing through the PMOS transistor group 102p is described as a current I1.

The node N2 is connected to the pad 102e. The pad 102e is connected to an end of the resistance element 102f. The other end of the resistance element 102f is connected to the ground potential. The resistance element 102f has a resistance value similar to a resistance value of the wiring resistance of the wire 101d in the first clock generator 101a or the second clock generator 101b. The resistance value of the resistance element 102f is, for example, 300 ohm. The resistance value of the resistance element 102f need not be 300 ohm but may be varied. In FIG. 3, a current flowing through the pad 102e and the resistance element 102f is described as a current I2. Since the resistance element 102f has a resistance value similar to the resistance value of the wiring resistance of the wire 101d, a voltage similar to a voltage supplied to the node N1 can be supplied to the node N2.

An inverting input of the comparator 102g is connected to the node N2. A reference voltage Vref1 is input to a non-inverting input of the comparator 102g. The comparator 102g operates based on a signal Pmos_trim_EN. The reference voltage Vref1 and the signal Pmos_trim_EN are, for example, supplied by the logic control circuit 105. However, the present embodiment is not limited to this. The main component that supplies the reference voltage Vref1 and the signal Pmos_trim_EN can be varied. The comparator 102g compares the voltage of the node N2 with the reference voltage Vref1 and outputs a result of the comparison. The comparator 102g outputs the “H” level while not in operation.

The NMOS trimming circuit 102c comprises a circuit similar to the circuits in the PMOS transistor group 101p and the NMOS transistor group 101n in the first clock generator 101a or the second clock generator 101b. The NMOS trimming circuit 102c adjusts a current flowing through the PMOS transistor group 101p and a current flowing through the NMOS transistor group 101n such that the currents are equal to each other.

The logic control circuit 105 generates the DAC value RONPdac related to the trimming signal RONN using the NMOS trimming circuit 102c. The NMOS trimming circuit 102c comprises a PMOS transistor group 102pn, an NMOS transistor group 102n, and a comparator 102h.

The PMOS transistor group 102pn is configured similarly to the PMOS transistor group 102p. The NMOS transistor group 102n is configured similarly to the NMOS transistor group 101n in the first clock generator 101a or the second clock generator 101b. In other words, the number of transistors included in the PMOS transistor group 102pn is equal to the number of transistors included in the PMOS transistor group 101p in the first clock generator 101a or the second clock generator 101b. Furthermore, the number of transistors included in the NMOS transistor group 102n is equal to the number of transistors included in the NMOS transistor group 101n in the first clock generator 101a or the second clock generator 101b.

The PMOS transistor group 102pn and the NMOS transistor group 102n are connected to a node N3. A non-inverting input of the comparator 102h is connected to the node N3. A reference voltage Vref2 is input to an inverting input of the comparator 102h. The comparator 102h operates based on a signal Nmos_trim_EN. The reference voltage Vref2 and the signal Nmos_trim_EN are, for example, supplied by the logic control circuit 105. However, the present embodiment is not limited to this. The main component that supplies the reference voltage Vref2 and the signal Nmos_trim_EN can be varied. The comparator 102h compares the voltage of the node N3 with the reference voltage Vref2 and outputs a result of the comparison. The comparator 102h outputs the “H” level while not in operation.

Operations of the trimming circuit 102a will be described below.

<1-2> Operations

<1-2-1> Basic Data Input and Output Operations

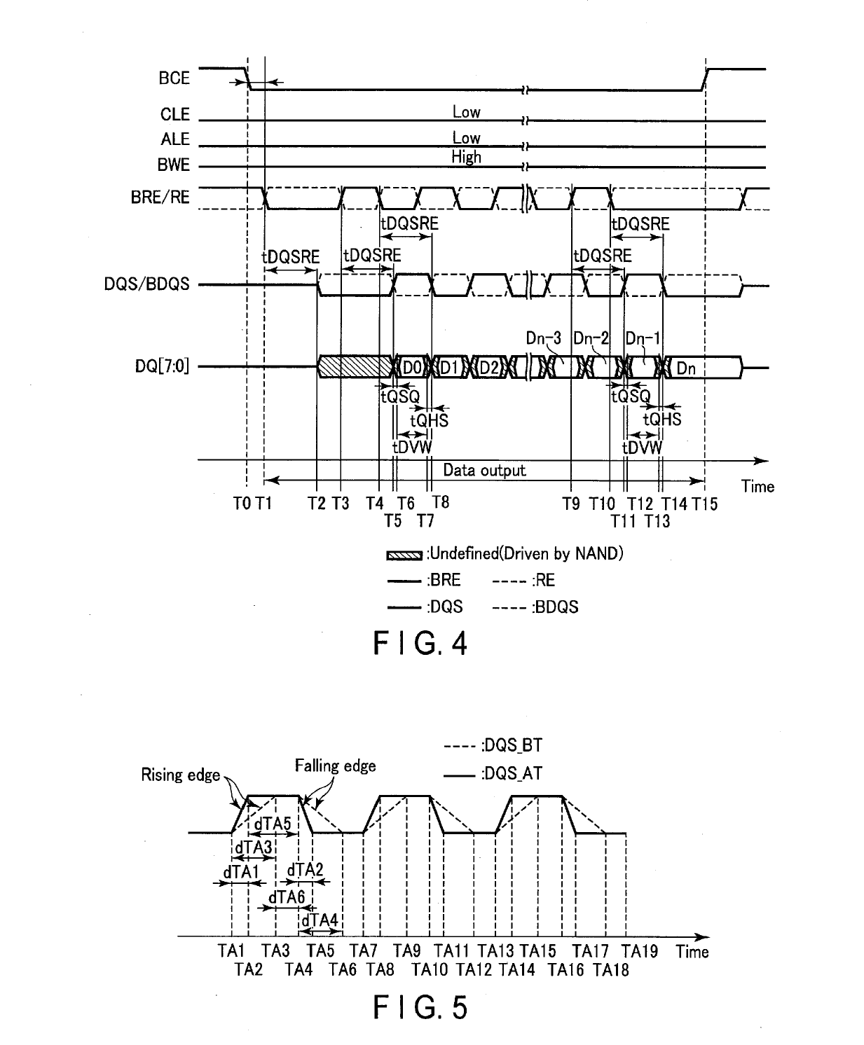

Data input and output operations of the memory chip according to the first embodiment will be described using FIG. 4.

[Time T0]

At time T0, the memory controller 200 causes the chip enable signal BCE to fall from the “H (High)” level to the “L (Low)” level.

[Time T1]

At time T1 corresponding to passage of a predetermined duration from time T0, the memory controller 200 causes the read enable signal RE to rise from the “L” level to the “H” level and causes the read enable signal BRE to fall from the “H” level to the “L” level.

[Time T2]

At time T2 corresponding to passage of duration tDQSRE from time T1, the input/output control circuit 103 supplies the trimming signal to the first clock generator 101a and the second clock generator 101b. The first clock generator 101a and the second clock generator 101b generate the data strobe signals DQS and BDQS based on the trimming signal and the read enable signals RE and BRE.

At time T2, the first clock generator 101a causes the data strobe signal DQS to fall to the “L” level. The second clock generator 101b causes the data strobe signal BDQS to rise to the “H” level.

[Time T3]

At time T3, the memory controller 200 causes the read enable signal RE to fall from the “H” level to the “L” level and causes the read enable signal BRE to rise from the “L” level to the “H” level.

[Time T4]

At time T4, the memory controller 200 causes the read enable signal RE to rise from the “L” level to the “L” level and causes the read enable signal BRE to fall from the “H” level to the “L” level.

[Time T5]

During time T3 to time T5, the first clock generator 101a causes the data strobe signal DQS to rise to the “H” level. The second clock generator 101b causes the data strobe signal BDQS to fall to the “L” level.

Thus, at time T5 corresponding to passage of duration tDQSRE from time T3, the level of the data strobe signal DQS crosses the level of the data strobe signal BDQS.

[Time T6]

At time T6 corresponding to passage of duration tQSQ from time T5, the input/output control circuit 103 starts outputting data D0.

[Time T7]

During time T6 to time T7 corresponding to passage of duration tDVW from time T6, the input/output control circuit 103 completes outputting the data D0.

[Time T8]

During time T4 to time T8, the first clock generator 101a causes the data strobe signal DQS to fall to the “L” level. The second clock generator 101b causes the data strobe signal BDQS to rise to the “H” level.

Thus, at time T8 corresponding to passage of duration tDQSRE from time T4, the level of the data strobe signal DQS crosses the level of the data strobe signal BDQS.

[Time T9] to [Time T15]

The operations during time T5 to time T8 are repeated. The input/output control circuit 103 outputs data D1 to Dn (n is a natural number) to the memory controller 200 based on the data strobe signals DQS and BDQS.

<1-2-2> Duration tDVW

As described above, the input/output control circuit 103 can output data to the memory controller 200 during duration tDVW defined by the data strobe signal DQS and BDQS. Duration tDVW is a period when the data strobe signals DQS and BDQS are at the “H” level or the “L” level.

A duration needed for the rise or fall of the waveforms of the data strobe lines DQS and BDQS (the gradient of the rise and the fall) varies according to the voltage supplied to the memory chip 100, the temperature of the memory chip 100, and the like.

Two types of data strobe lines DQS in different situations will be described using FIG. 5. A description of the data strobe line BDQS is similar to the description of the data strobe signal DQS and is thus omitted.

As depicted in FIG. 5, a data strobe line DQS_AT rises from the “L” level to the “H” level during time TA1 to time TA2 (dTA1). The data strobe line DQS_AT falls from the “H” level to the “L” level during time TA4 to time TA5 (dTA2).

The data strobe line DQS_BT rises from the “L” level to the “H” level during duration dTA3 (dTA3>dTA1) from time TA1 to time TA3. The data strobe line DQS_BT falls from the “H” level to the “L” level during duration dTA4 (dTA4>dTA2) from time TA4 to time TA6.

Duration tDVW for the data strobe line DQS_AT is based on duration dTA5 from time TA2 to time TA4 during which the data strobe line DQS_AT is at the “H” level. Furthermore, duration tDVW for the data strobe line DQS_BT is based on duration dTA6 from time TA3 to time TA4 during which the data strobe line DQS_BT is at the “H” level (dTA6<dTA5).

Thus, duration tDVW decreases with increasing duration needed for the rise or fall of the waveform of the data strobe line DQS (as the gradient is closer to 180 degrees). For example, a reduced duration tDVW may preclude appropriate transmission and reception of data between the memory chip 100 and the memory controller 200. In particular, when the memory chip 100 is operated at a high speed, duration tDVW decreases in proportion to the speed of the operation. Thus, when the memory chip 100 is operated at a high speed, appropriate transmission and reception of data may be precluded.

The duration needed for the rise or fall of the waveform of the data strobe signal DQS (the gradient of the rise or the fall) varies in accordance with the trimming control signal supplied to the first clock generator 101a.

Thus, the memory chip 100 according to the present embodiment generates the appropriate trimming control signal using the trimming circuit 102a.

<1-2-3> Operation of Generating the Trimming Control Signal

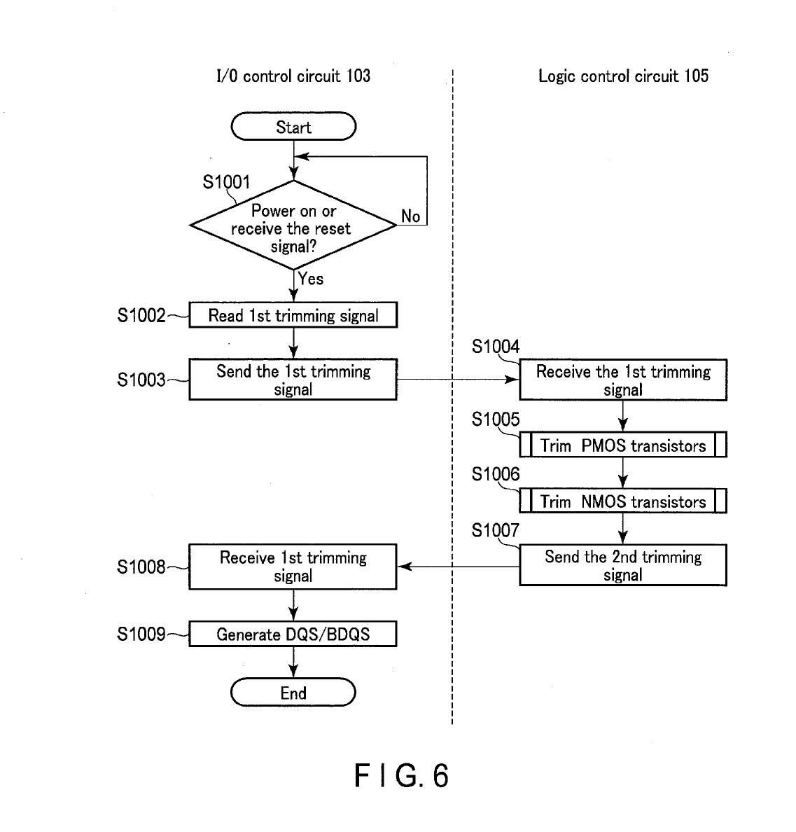

Operations for generating the trimming control signal will be described using FIG. 6.

[Step S1001]

The input/output control circuit 103 determines whether or not the memory chip 100 has been powered on or a reset signal has been received.

[Step S1002]

Upon determining that the memory chip 100 has been powered on or the reset signal has been received (step S1001, YES), the input/output control circuit 103 reads a first trimming control signal from the trimming signal register 103a. The first trimming control signal may have an initial value or may be the latest trimming control signal stored in the trimming signal register 103a.

[Step S1003]

The input/output control circuit 103 supplies the first trimming control signal to the logic control circuit 105.

[Step S1004]

The logic control circuit 105 receives the first trimming control signal from the input/output control circuit 103.

[Step S1005]

Upon receiving the first trimming control signal, the logic control circuit 105 starts generating the trimming control signal for the PMOS transistor group 101p, using the PMOS trimming circuit 102b in the trimming circuit 102a.

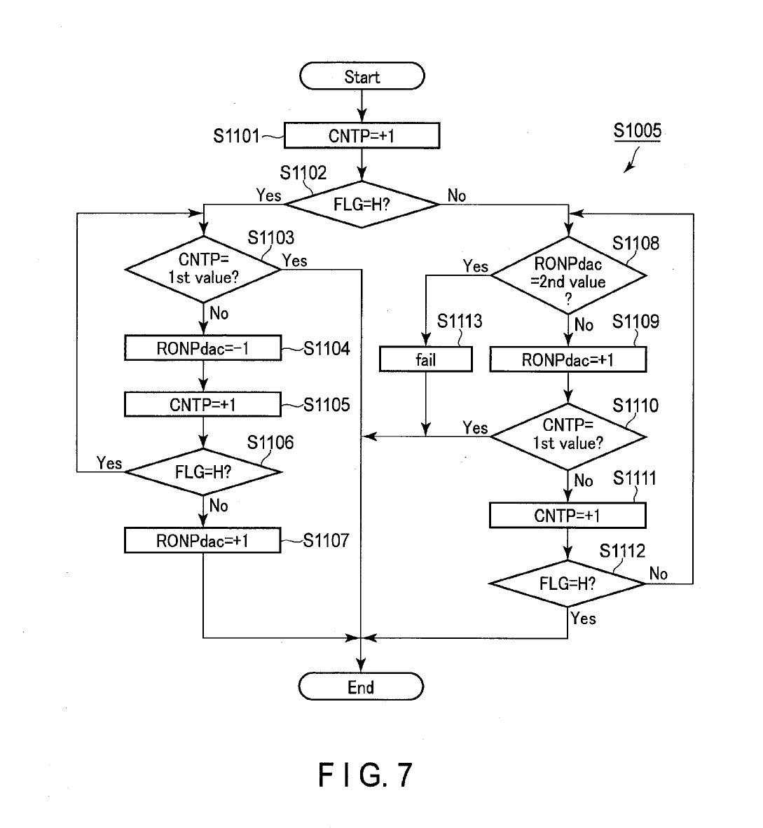

Trimming for the PMOS transistor will be described using FIG. 7 and FIG. 3.

In brief, in the trimming for the PMOS transistors, the memory chip 100 generates such a DAC value RONPdac as makes the voltage of the node N2 and the reference voltage Vref1 substantially the same, using the trimming circuit 102a.

[Step S1101]

The logic control circuit 105 counts a counter value CNTP up by “1”. The counter value CNTP is counted, for example, by a counter provided inside the logic control circuit 105. The counter value CNTP is reset to an initial value by the logic control circuit 105 before step S1101 is started. An upper limit (first value) of the counter value CNTP may, for example, be stored in the memory cell array 110.

[Step S1102]

The logic control circuit 105 supplies the trimming signal RONP to the PMOS transistor group 102p based on the DAC value RONPdac for the PMOS trimming, which is contained in the first trimming control signal. For example, when the DAC value RONPdac is “5”, the logic control circuit 105 determines the trimming signal RONP such that “five” PMOS transistors in the PMOS transistor group 102p are set to an on state. Specifically, for example, when the DAC value RONPdac is “5”, the trimming signals RONP0 to RONP4 are set to the “H” level, and the trimming signals RONP5 to RONP30 are set to the “L” level. In other words, the logic control circuit 105 determines the number of trimming signals RONP to be set to the “H” level based on the DAC value RONPdac. In other words, the DAC value RONPdac corresponds to the number of transistors in the PMOS transistor group 102p to be operated.

Then, the PMOS trimming circuit 102b compares the voltage of the node N2 with the reference voltage Vref1, and outputs a result of the comparison to the NAND circuit 102d. When the NMOS trimming circuit 102c is not operated, an output value from the NMOS trimming circuit 102c is at the “H” level. The logic control circuit 105 determines whether or not an output value FLG from the NAND circuit 102d depicted in FIG. 3 is at the “H” level.

[Step S1103]

Upon determining in step S1102 or S1106 that the output value FLG is at the “H” level (steps S1102, S1106, YES), the logic control circuit 105 determines whether or not the counter value CNTP is the first value.

Upon determining that the counter value CNTP is the first value (step S1103, YES), the logic control circuit 105 ends the operation in step S1005.

[Step S1104]

Upon determining that the counter value CNTP is not the first value (step S1103, NO), the logic control circuit 105 reduces the DAC value RONPdac by “1”. Reducing the DAC value RONPdac by “1” means reducing the number of PMOS transistors in the PMOS transistor group 102p to be operated by “1”. The DAC value RONPdac is counted, for example, by an up-down counter provided inside the logic control circuit 105. An upper limit (second value) of the DAC value RONPdac may be stored, for example, in the memory cell array 110.

[Step S1105]

The logic control circuit 105 counts the counter value CNTP up by “1”.

[Step S1106]

The logic control circuit 105 supplies the trimming signal RONP to the PMOS transistor group 102p based on the DAC value RONPdac determined in step S1104. Then, the PMOS trimming circuit 102b compares the voltage of the node N2 with the reference voltage Vref1 and outputs a result of the comparison to the NAND circuit 102d. The logic control circuit 105 determines whether or not the output value FLG from the NAND circuit 102d is at the “H” level.

[Step S1107]

Upon determining in step S1106 that the output value FLG is at the “L” level (step S1106, NO), the logic control circuit 105 increase the DAC value RONPdac by “1” and ends the operation in step S1005.

[Step S1108]

Upon determining in step S1102 or S1112 that the output value FLG is at the “L” level (steps S1102, S1112, NO), the logic control circuit 105 determines whether or not the DAC value RONPdac is the second value.

[Step S1109]

Upon determining in step S1108 that the DAC value RONPdac is not the second value, the logic control circuit 105 increases the DAC value RONPdac by “1”.

[Step S1110]

The logic control circuit 105 determines whether or not the counter value CNTP is the first value.

Upon determining that the counter value CNTP is the first value (step S1110, YES), the logic control circuit 105 ends the operation in step S1005.

[Step S1111]

Upon determining that the counter value CNTP is not the first value (step S1110, NO), the logic control circuit 105 counts the counter value CNTP up by “1”.

[Step S1112]

The logic control circuit 105 supplies the trimming signal RONP to the PMOS transistor group 102p based on the DAC value RONPdac determined in step S1109. Then, the PMOS trimming circuit 102b compares the voltage of the node N2 with the reference voltage Vref1 and outputs a result of the comparison to the NAND circuit 102d. The logic control circuit 105 determines whether or not the output value FLG from the NAND circuit 102d is at the “H” level.

Upon determining in step S1112 that the output value FLG is at the “H” level (step S1112, YES), the logic control circuit 105 ends the operation in step S1005.

[Step S1113]

Upon determining in step S1108 that the DAC value RONPdac is the second value (step S1108, YES), the logic control circuit 105 generates “Fail” meaning a failure in the PMOS trimming to end the operation of generating the trimming control signal.

[Step S1006]

With reference back to the flow in FIG. 6, operations following step S1005 will be described. Upon ending the operation in step S1005, the logic control circuit 105 starts trimming for the NMOS transistor using the NMOS trimming circuit 102c in the trimming circuit 102a.

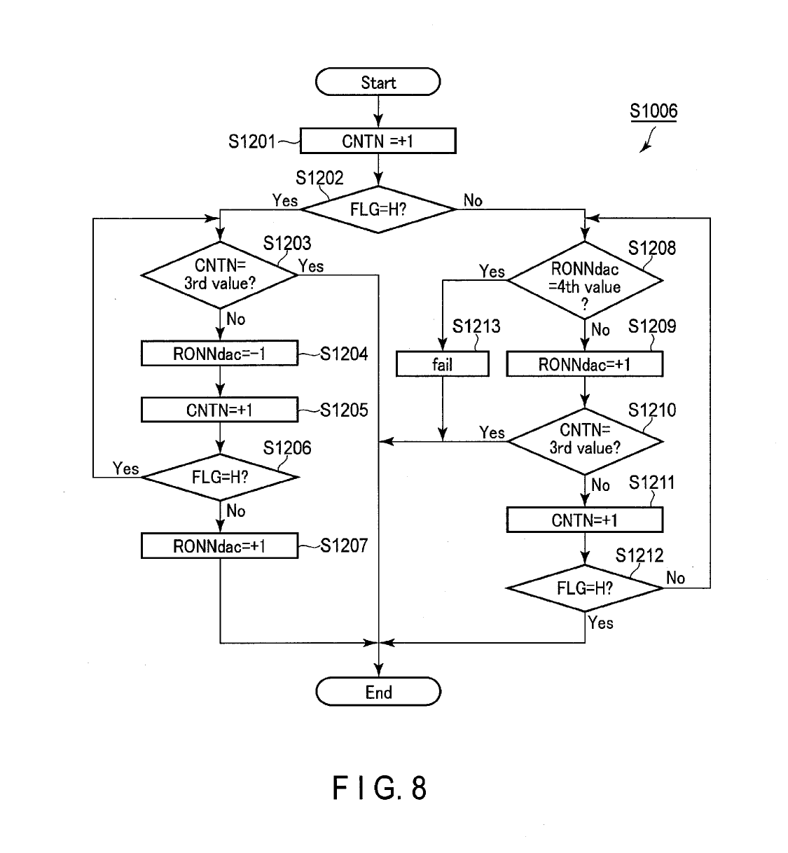

The trimming for the NMOS transistor will be described using FIG. 8 and FIG. 3.

In brief, in the trimming for the NMOS transistor, the memory chip 100 generates such a DAC value RONNdac as makes the voltage of the node N3 and the reference voltage Vref2 substantially the same, using the trimming circuit 102a.

[Step S1201]

The logic control circuit 105 counts up a counter value CNTN by “1”. The counter value CNTN is counted, for example, by the counter provided inside the logic control circuit 105. The counter value CNTN is reset to an initial value by the logic control circuit 105 before step S1201 is started. An upper limit (third value) of the counter value CNTN may, for example, be stored in the memory cell array 110.

[Step S1202]

The logic control circuit 105 supplies the trimming signal RONN to the NMOS transistor group 102n based on the DAC value RONNdac for the NMOS trimming, which is contained in the first trimming control signal. Furthermore, the logic control circuit 105 supplies the trimming signal RONP to the PMOS transistor group 102pn based on the DAC value RONPdac for the NMOS trimming, which is derived based on step S1005. The logic control circuit 105 determines the number of trimming signals RONN to be set to the “H” level based on the DAC value RONNdac. In other words, the DAC value RONNdac corresponds to the number of transistors in the NMOS transistor group 102n to be operated.

Then, the NMOS trimming circuit 102c compares the voltage of the node N3 with the reference voltage Vref2, and outputs a result of the comparison to the NAND circuit 102d. When the PMOS trimming circuit 102b is not operated, an output value from the NMOS trimming circuit 102c is at the “H” level. The logic control circuit 105 determines whether or not the output value FLG from the NAND circuit 102d is at the “H” level.

[Step S1203]

Upon determining in step S1202 or S1206 that the output value FLG is at the “H” level (steps S1202, S1206, YES), the logic control circuit 105 determines whether or not the counter value CNTN is the third value.

Upon determining that the counter value CNTN is the third value (step S1203, YES), the logic control circuit 105 ends the operation in step S1006.

[Step S1204]

Upon determining that the counter value CNTP is not the third value (step S1203, NO), the logic control circuit 105 reduces the DAC value RONNdac by “1”. The DAC value RONNdac is counted, for example, by the up-down counter provided inside the logic control circuit 105. An upper limit (fourth value) of the DAC value RONNdac may be stored, for example, in the memory cell array 110.

[Step S1205]

The logic control circuit 105 counts the counter value CNTN up by “1”.

[Step S1206]

The logic control circuit 105 supplies the trimming signal RONN to the NMOS transistor group 102n based on the DAC value RONNdac determined in step S1204. Furthermore, the logic control circuit 105 supplies the trimming signal RONP to the PMOS transistor group 102pn based on the DAC value RONPdac determined in step S1005. Then, the NMOS trimming circuit 102c compares the voltage of the node N3 with the reference voltage Vref2 and outputs a result of the comparison to the NAND circuit 102d. The logic control circuit 105 determines whether or not the output value FLG from the NAND circuit 102d is at the “H” level.

[Step S1207]

Upon determining in step S1206 that the output value FLG is at the “L” level (step S1206, NO), the logic control circuit 105 increase the DAC value RONNdac by “1” and ends the operation in step S1006.

[Step S1208]

Upon determining in step S1202 or S1212 that the output value FLG is at the “L” level (steps S1202, S1212, NO), the logic control circuit 105 determines whether or not the DAC value RONNdac is the fourth value.

[Step S1209]

Upon determining in step S1208 that the DAC value RONNdac is not the fourth value, the logic control circuit 105 increases the DAC value RONNdac by “1”.

[Step S1210]

The logic control circuit 105 determines whether or not the counter value CNTN is the third value.

Upon determining that the counter value CNTN is the third value (step S1110, YES), the logic control circuit 105 ends the operation in step S1006.

[Step S1211]

Upon determining that the counter value CNTP is not the third value (step S1210, NO), the logic control circuit 105 counts the counter value CNTN up by “1”.

[Step S1212]

The logic control circuit 105 supplies the trimming signal RONN to the NMOS transistor group 102n based on the DAC value RONNdac determined in step S1209. Then, the NMOS trimming circuit 102c compares the voltage of the node N3 with the reference voltage Vref2 and outputs a result of the comparison to the NAND circuit 102d. The logic control circuit 105 determines whether or not the output value FLG from the NAND circuit 102d is at the “H” level.

Upon determining in step S1212 that the output value FLG is at the “H” level (step S1212, YES), the logic control circuit 105 ends the operation in step S1006.

[Step S1213]

Upon determining in step S1208 that the DAC value RONNdac is the fourth value (step S1208, YES), the logic control circuit 105 generates “Fail” meaning a failure in the NMOS trimming to end the operation of generating the trimming control signal.

[Step S1007]

With reference back to the flow in FIG. 6, operations following step S1006 will be described. Upon ending the operation in step S1006, the logic control circuit 105 transmits the DAC value RONPdac obtained at the end of step S1005 and the DAC value RONNdac obtained at the end of step S1006 to the input/output control circuit 103 as a second trimming control signal.

[Step S1008]

The input/output control circuit 103 receives and stores the second trimming control signal in the trimming signal register 103a.

[Step S1009]

The input/output control circuit 103 transmits the trimming signals RONP and RONN to the first clock generator 101a based on the second trimming control signal and the read enable signal RE (or BRE). Furthermore, the input/output control circuit 103 transmits the trimming signals RONP and RONN to the second clock generator 101b based on the second trimming control signal and the read enable signal BRE (or RE). The first clock generator 101a generates the data strobe signal DQS based on the trimming signals RONP and RONN. Additionally, the second clock generator 101b generates the data strobe signal BDQS based on the trimming signals RONP and RONN.

The memory chip 100 generates the data strobe signals DQS and BDQS using the second trimming control signal stored in the trimming signal register 103a unless the memory chip 100 is powered off or the reset command or the like is input to the memory chip 100. The memory chip 100 repeats the operation in step S1002 when the memory chip 100 is powered off or the reset command or the like is input to the memory chip 100.

In the above-described operation, the input/output control circuit 103 performs the operation of generating the trimming control signal upon determining that the memory chip 100 has been powered off or has received the reset command. However, the present embodiment is not limited to this. For example, the operation of generating the trimming control signal may be performed periodically or based on a particular command.

<1-3> Effects of the Present Embodiment

According to the above-described embodiment, the memory chip 100 comprises the trimming circuit 102a comprising a circuit similar to the circuits in the first clock generator 101a and the second clock generator 101b. As described above, the trimming circuit 102a generates a current similar to the current generated in the first clock generator 101a or the second clock generator 101b. The memory chip 100 adjusts the number of PMOS transistors to be turned on so as to allow the PMOS transistor group 102p to generate the appropriate current. Furthermore, the memory chip 100 adjusts the number of NMOS transistors to be turned on so as to allow the NMOS transistor group 101n to generate the appropriate current. Then, the memory chip 100 generates the trimming signal based on the result of the adjustment. The memory chip 100 then allows the first clock generator 101a or the second clock generator 101b to generate the data strobe signal using the generated trimming signal.

The first clock generator 101a or the second clock generator 101b is trimmed so as to generate the appropriate current based on the trimming signal. This optimizes the duration needed for the rise and fall of the data strobe signal. As a result, the rise and fall of the data strobe signal have the optimum gradients. In other words, the memory chip 100 provides duration tDVW needed to transmit data to the memory controller 200. As a result, even when the memory chip 100 is operated at a high speed, data can be appropriately transmitted and received between the memory chip 100 and the memory controller 200.

### <2> Second Embodiment

Now, a second embodiment will be described. In the second embodiment, a modification of the trimming circuit will be described. A basic configuration and basic operations of a memory device according to the second embodiment are similar to the basic configuration and the basic operations of the memory device according to the first embodiment. Therefore, matters described above in the first embodiment and easily estimated from the first embodiment will not be described below.

<2-1> Basic Configuration of the Trimming Circuit

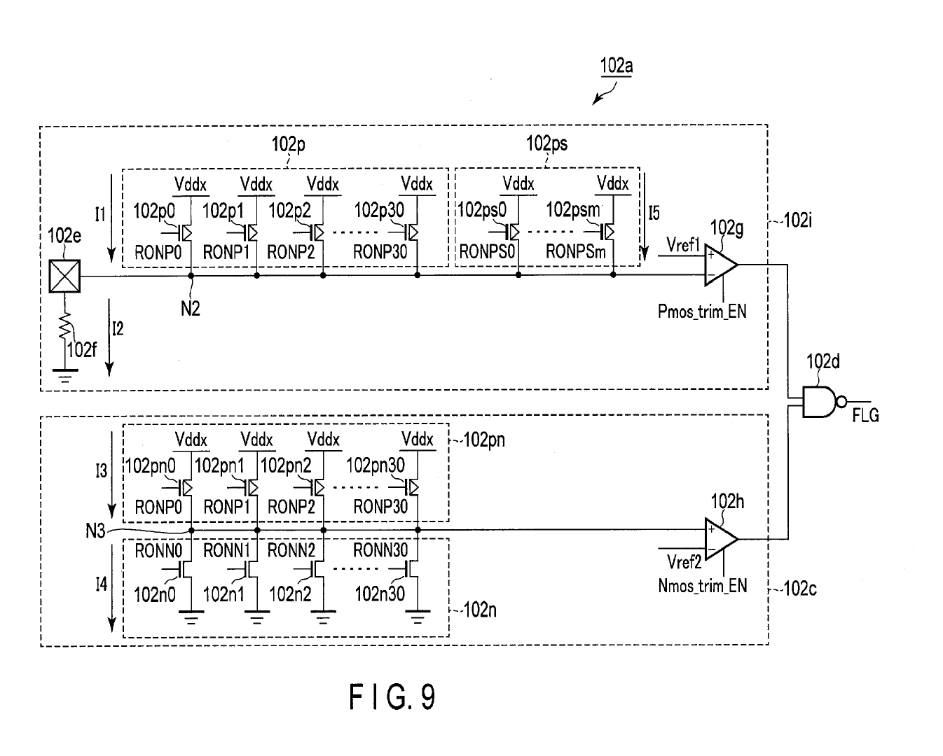

The second trimming circuit 102a will be described using FIG. 9. The trimming circuit 102a generates the trimming control signal using a PMOS trimming circuit 102i, the PMOS trimming circuit 102b, the NMOS trimming circuit 102c, and the NAND circuit 102d.

The PMOS trimming circuit 102i comprises the PMOS transistor group 102p, a sub-PMOS-transistor-group 102p, the pad 102e, the resistance element 102f, and the comparator 102g.

The sub-PMOS-transistor-group 102ps comprises m+1 (m is an integer) PMOS transistors (102ps0 to 102psm). The trimming signal RONP0 is input to a gate of the PMOS transistor 102ps0. The voltage Vddx is applied to an end (source) of the PMOS transistor 102ps0. The other end (drain) of the PMOS transistor 102ps0 is connected to the node N2. Trimming signals RONPS1 to RONPSm are input to gates of the PMOS transistors 102ps1 to 102psm. The voltage Vddx is applied to ends (sources) of the PMOS transistors 102ps1 to 102psm. The other ends of the PMOS transistors 102ps1 to 102psm are connected to the node N2. In FIG. 9, the sum of currents flowing through the sub-PMOS-transistor-group 102ps is described as I5.

The number of transistors included in the sub-PMOS-transistor-group 102ps can be changed as needed regardless the number of transistors included in the PMOS transistor group 101p in the first clock generator 101a or the second clock generator 101b.

<2-2> Operation of Generating the Trimming Control Signal

An operation of generating the trimming control signal according to the second embodiment will be described.

A basic operation of generating the trimming control signal is similar to the operation described with reference to FIG. 6.

The following description focuses on the operation in step S1005 in FIG. 6, which is modified in the second embodiment.

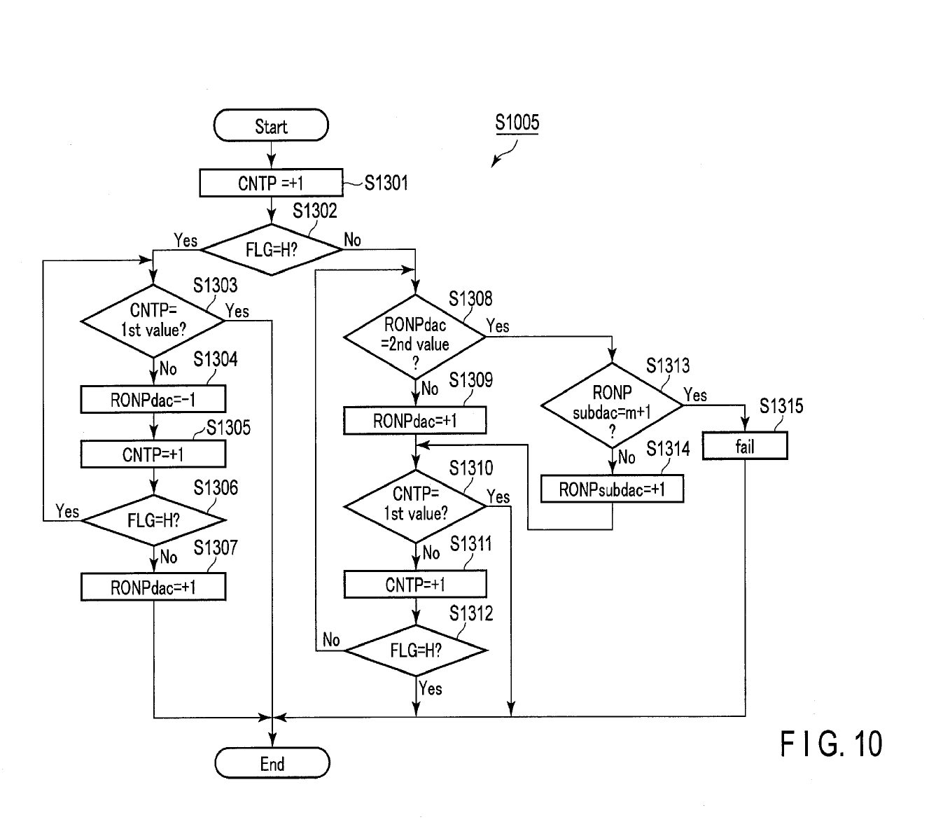

A modification of the trimming for the PMOS transistors will be described using FIG. 10 and FIG. 9.

[Step S1301] to [Step S1312]

The memory chip 100 performs operations similar to the operations in steps S1101 to S1112.

[Step S1313]

Upon determining in step S1308 that the DAC value RONPdac is the second value (step S1308, YES), the logic control circuit 105 determines whether or not a sub-DAC-value RONPsubdac is “m+1”. The sub-DAC-value RONPsubdac corresponds to the number of transistors in the PMOS transistor group 102ps to be operated. An initial value of the sub-DAC-value RONPsubdac is, for example, zero. The sub-DAC-value RONPsubdac is counted, for example, by the up-down counter provided inside the logic control circuit 105. An upper limit (m+1) of the sub-DAC-value RONPsubdac may be stored, for example, in the memory cell array 110.

[Step S1314]

Upon determining that the sub-DAC-value RONPsubdac is not “m+1” (step S1313, NO), the logic control circuit 105 increases the sub-DAC-value RONPsubdac by “1”. Reducing the sub-DAC-value RONPsubdac by “1” means reducing the number of PMOS transistors in the sub-PMOS-transistor-group 102ps to be operated by “1”. The sub-DAC-value RONPsubdac is not included in the trimming control signal supplied to the first clock generator 101a or the second clock generator 101b.

Consequently, in step S1312, the logic control circuit 105 supplies the trimming signal RONP to the PMOS transistor group 102p based on the DAC value RONPdac determined in step S1309. Furthermore, the logic control circuit 105 supplies the trimming signal RONPS to the sub-PMOS-transistor-group 102ps based on the sub-DAC-value RONPdac determined in step S1314.

Then, the PMOS trimming circuit 102b compares the voltage of the node N2 with the reference voltage Vref1 and outputs a result of the comparison to the NAND circuit 102d. The logic control circuit 105 determines whether or not the output value FLG from the NAND circuit 102d is at the “H” level.

Upon determining in step S1312 that the output value FLG is at the “H” level (step S1312, YES), the logic control circuit 105 ends the operation in step S1005.

[Step S1315]

Upon determining in step S1313 that the sub-DAC-value RONPsubdac is “m+1” (step S1313, YES), the logic control circuit 105 generates “Fail” meaning a failure in the PNMOS trimming to end the operation of generating the trimming control signal.

[Step S1007]

With reference back to the flow in FIG. 6, operations following step S1006 will be described. Upon ending the operation in step S1006, the logic control circuit 105 transmits the DAC value RONPdac obtained at the end of step S1005 and the DAC value RONNdac obtained at the end of step S1006 to the input/output control circuit 103 as the second trimming control signal. As described above, the sub-DAC-value RONPsubdac is not included in the second trimming control signal.

<2-3> Effects

According to the above-described embodiment, the trimming circuit 102a comprises the sub-PMOS-transistor-group 102ps. The trimming circuit 102a uses the sub-PMOS-transistor-group 102ps to restrain the trimming for the PMOS transistors from resulting in “fail”.

As described in <1-2-2>, when the memory chip 100 is operated at a high speed, a reduced duration tDVW may preclude correct transmission and reception of data between the memory chip 100 and the memory controller 200.

Thus, for example, in tests prior to shipment of the memory chip 100, the memory chip 100 is operated at a high speed, and whether or not the operation of generating the trimming control signal using the trimming circuit 102a results in “fail” is determined. Memory chips 100 are disposed of in which the operation of generating the trimming control signal using the trimming circuit 102a results in “fail”. However, memory chips 100 to be disposed of may provide a sufficient duration tDVW if the memory chips 100 are not operated at a high speed. Whether the memory chip 100 is operated at a high speed depends on a user. Thus, users who do not operate the memory chip 100 at a high speed do not reject the memory chips 100 that are otherwise disposed of.

The trimming circuit 102a according to the above-described embodiment is provided with the sub-PMOS-transistor-group 102ps to enable generation of a current larger than the current generated in the first clock generator 101a. Thus, compared to the trimming circuit 102a according to the first embodiment, the trimming circuit 102a according to the second embodiment enables relaxation of a condition for the tests prior to the shipment of the memory chip 100 under which the operation of generating the trimming control signal results in “fail”.

As a result, memory chips that avoid being rejected depending on the user can be restrained from being disposed of, resulting in an increased manufacturing yield of the memory chip 100.

Furthermore, in the embodiments relating to the present invention,

(1) In the read operation,

a voltage applied to word lines selected for a read operation at an A level is, for example, between 0 V and 0.55 V, the present invention is not limited to this, and the voltage may be between 0.1 V and 0.24 V, between 0.21 V and 0.31 V, between 0.31 V and 0.4 V, between 0.4 V and 0.5 V, or between 0.5 V and 0.55 V,

a voltage applied to word lines selected for a read operation at a B level is, for example, between 1.5 V and 2.3 V, the present invention is not limited to this, and the voltage may be between 1.65 V and 1.8 V, between 1.8 V and 1.95 V, between 1.95 V and 2.1 V, or between 2.1 V and 2.3 V,

a voltage applied to word lines selected for a read operation at a C level is, for example, between 3.0 V and 4.0 V, the present invention is not limited to this, and the voltage may be between 3.0 V and 3.2 V, between 3.2 V and 3.4 V, between 3.4 V and 3.5 V, between 3.5 V and 3.6 V, or between 3.6 V and 4.6 V, and

the duration (tR) of the read operation may be, for example, between 25 μs and 38 μs, between 38 μs and 70 μs, or between 70 μs and 80 μs.

(2) A write operation includes a program operation and a verify operation as described above. In the write operation,

a voltage applied first to word lines selected during the program operation is, for example, between 13.7 V and 14.3 V, the present invention is not limited to this, and the voltage may be between 13.7 V and 14.0 V or between 14.0 V and 14.6 V, and

a voltage applied first to word lines selected when the write operation is performed on odd-numbered word lines may be interchanged with a voltage applied first to word lines selected when the write operation is performed on even-numbered word lines,

when the program operation is based on an ISPP scheme (Incremental Step Pulse Program), a step-up voltage may be, for example, approximately 0.5 V,

a voltage applied to unselected word lines may be, for example, between 6.0 V and 7.3 V. The present invention is not limited to this, and the voltage may be, for example, between 7.3 V and 8.4 V or 6.0 V or lower,

a pass voltage to be applied may be varied depending on whether the unselected word lines are odd-numbered word lines or even-numbered word lines, and

the duration (tProg) of the write operation may be, for example, between 1700 μs and 1800 μs, between 1800 μs and 1900 μs, or between 1900 μs and 2000 μs.

(3) In an erase operation,

a voltage applied first to a well formed in an upper portion of a semiconductor substrate and above which the memory cell is arranged is, for example, between 12 V and 13.6 V, the present invention is not limited to this, and the voltage may be between 13.6 V and 14.8 V, between 14.8 V and 19.0 V, between 19.0 V and 19.8 V, or between 19.8 V and 21 V, and

the duration (tErase) of the erase operation may be, for example, between 3000 μs and 4000 μs, between 4000 μs and 5000 μs, or between 4000 us and 9000 μs.

(4) The memory cell is structured as follows.

A charge storage layer is arranged on the semiconductor substrate (silicon substrate) via a tunnel insulating film with a film thickness of 4 to 10 nm. The charge storage layer may have a stack structure with an insulating film of SiN, SiON, or the like having a film thickness of 2 to 3 nm and polysilicon having a film thickness of 3 to 8 nm. Furthermore, metal such as Ru may be added to the polysilicon. An insulating film is provided on the charge storage layer. The insulating film has a lower High-k film with a film thickness of 3 to 10 nm, an upper High-k film with a film thickness of 3 to 10 nm, and a silicon oxide film with a thickness of 4 to 10 nm sandwiched the lower High-k film and the upper High-k film. The High-k films may be HfO. Furthermore, the film thickness of the silicon oxide film may be larger than the film thickness of the High-k films. A control electrode with a film thickness of 30 to 70 nm is formed on the insulating film via a material with a film thickness of 3 to 10 nm. In this regard, a material for adjustment of a work function may be a metal oxide film such as TaO or a metal nitride film such as TaN. W or the like may be used for the control electrode.

Furthermore, an air gap may be formed between the memory cells.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A memory device comprising:
a memory cell array configured to store data; and
a clock generator configured to generate a clock signal,
wherein the memory device outputs data held in the memory cell array in accordance with a timing of the clock signal, and
the clock generator generates the clock signal with a substantially constant gradient each time a power supply is turned on.

2. The memory device according to claim 1, further comprising a trimming circuit configured to generate a first signal,
wherein the clock generator adjusts the clock signal using the first signal.

3. The memory device according to claim 2, wherein the clock generator comprises a first transistor group and a second transistor group, and
the trimming circuit comprises a third transistor group and a fourth transistor group each including transistors identical in number to transistors in the first transistor group;
a resistance element connected to a first end of the third transistor group;
a first comparator connected to the first end of the third transistor group;
a fifth transistor group including transistors identical in number to transistors in the second transistor group; and
a second comparator connected to second ends of the fourth transistor group and the fifth transistor group.

4. The memory device according to claim 3, wherein the trimming circuit further comprises a sixth transistor group connected to the first end of the third transistor group.

5. The memory device according to claim 4, wherein the first signal is generated based on the third transistor group, the fourth transistor group, and the fifth transistor group.

6. The memory device according to claim 3, wherein a plurality of transistors included in the first transistor group, a plurality of transistors in the third transistor group, and a plurality of transistors in the fourth transistor group are transistors of a first conductivity type, and
a plurality of transistors included in the second transistor group and a plurality of transistors included in the fifth transistor group are transistors of a second conductivity type that is different from the first conductivity type.

7. The memory device according to claim 4, wherein the first transistor group, the third transistor group, the fifth transistor group, and the sixth transistor group each comprise a plurality of transistors of a first conductivity type, and
the second transistor group and the fourth transistor group each comprise a plurality of transistors of a second conductivity type that is different from the first conductivity type.

8. The memory device according to claim 2, wherein the clock generator comprises a first circuit configured to cause the clock signal to rise and a second circuit configured to cause the clock signal to fall,
the first signal comprises a second signal that controls the first circuit and a third signal that controls the second circuit, and
the trimming circuit comprises a third circuit configured to generate the second signal and a fourth circuit configured to generate the third signal.

9. The memory device according to claim 8, wherein the first circuit comprises a first transistor group,
the second circuit comprises a second transistor group,
the third circuit comprises a third transistor group comprising transistors that are identical in number to transistors in the first transistor group, and
the fourth circuit comprises a fourth transistor group comprising transistors that are identical in number to transistors in the first transistor group and a fifth transistor group comprising transistors that are identical in number to transistors in the second transistor group.

10. The memory device according to claim 9, wherein the third circuit comprises a resistance element connected to a first end of the third transistor group; and
a first comparator connected to the first end of the third transistor group, and
the fourth circuit comprises a second comparator connected to second ends of the fourth transistor group and the fifth transistor group.

11. The memory device according to claim 10, wherein the third circuit further comprises a sixth transistor group connected to a first end of the third transistor group.

12. The memory device according to claim 11, wherein the first signal is generated based on the third transistor group, the fourth transistor group, and the fifth transistor group.

13. The memory device according to claim 9, wherein a plurality of transistors included in the first transistor group, a plurality of transistors in the third transistor group, and a plurality of transistors in the fifth transistor group are transistors of a first conductivity type, and
a plurality of transistors included in the second transistor group and a plurality of transistors included in the fourth transistor group are transistors of a second conductivity type that is different from the first conductivity type.

14. The memory device according to claim 11, wherein the first transistor group, the third transistor group, the fifth transistor group, and the sixth transistor group each comprise a plurality of transistors of a first conductivity type, and
the second transistor group and the fourth transistor group each comprise a plurality of transistors of a second conductivity type that is different from the first conductivity type.

15. A memory system comprising:
a controller; and
a memory device,
wherein the memory device comprises:
a memory cell array configured to store data; and
a clock generator configured to generate a clock signal,
the controller receives data held in the memory cell array in accordance with a timing of the clock signal, and
the clock generator generates the clock signal with a substantially constant gradient each time a power supply is turned on.

16. The memory system according to claim 15, further comprising a trimming circuit configured to generate a first signal,
wherein the clock generator adjusts the clock signal using the first signal.

17. The memory system according to claim 16, wherein the clock generator comprises a first transistor group and a second transistor group, and
the trimming circuit comprises a third transistor group similar to the first transistor group, a fourth transistor group, and a fifth transistor group similar to the second transistor group.

18. The memory system according to claim 17, wherein the trimming circuit comprises:
a resistance element connected to a first end of the third transistor group;
a first comparator connected to the first end of the third transistor group; and
a second comparator connected to second ends of the fourth transistor group and the fifth transistor group.

19. The memory system according to claim 18, wherein the trimming circuit further comprises a sixth transistor group connected to the first end of the third transistor group.

20. The memory system according to claim 19, wherein the first signal is generated based on the third transistor group, the fourth transistor group, and the fifth transistor group.
